(19) United States
(12) Patent Application Publication
(10) Pub. No.: US 2026/0344467 A1
(43) Pub. Date: Oct. 29, 2026

(54) Semiconductor Device and Method of Making Including Encapsulated Pair Interconnect Structures

(71) Applicant: STATS ChipPAC Pte. Ltd., Singapore (SG)

(72) Inventors: Linda Pei Ee Chua, Singapore (SG); Swain Hong Alfred Yeo, Singapore (SG); Yi Jing Eric Chong, Singapore (SG); Rex Robles Dela Cerna, Singapore (SG)

(73) Assignee: STATS ChipPAC Pte. Ltd., Singapore (SG)

(21) Appl. No.: 19/193,349

(22) Filed: Apr. 29, 2025

(51) Int. Cl. H10W 70/63; H10W 70/05; H10W 70/09; H10W 70/652; H10W 74/10

(52) U.S. Cl. CPC H10W 70/635; H10W 70/095; H10W 70/09; H10W 70/6528; H10W 74/111

(57) ABSTRACT

A semiconductor device has a plurality of encapsulated pair interconnect structures. The encapsulated pair interconnect structures each have a first conductive pillar and second conductive pillar. An encapsulant is deposited over the first conductive pillar and second conductive pillar. A first and second encapsulated pair interconnect structure are disposed on opposite sides of a semiconductor die. A second encapsulant is deposited over the semiconductor die, first encapsulated pair interconnect structure, and second encapsulated pair interconnect structure to form a panel. A build-up interconnect structure is formed over the panel. The panel is singulated through the first encapsulated pair interconnect structure and second encapsulated pair interconnect structure between the respective first conductive pillar and second conductive pillar of each encapsulated pair interconnect structure.

### FIELD OF THE INVENTION

The present invention relates in general to semiconductor devices and, more particularly, to semiconductor devices and methods of making including encapsulated pair interconnect structures.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Vertical interconnect structures, e.g., conductive pillars, are commonly pre-molded and then embedded in a semiconductor package after being separately molded. The pre-molded interconnect structures are formed as a strip or block of multiple pillars to improve efficiency. However, current methods have many weaknesses. One issue is that current pick-and-place methods limit the usable length-to-width aspect ratio. Narrow and long packages may lead to crack issues during pick and place of the longer blocks of vertical interconnect structures. Accordingly, a need exists for new semiconductor devices and methods of making including encapsulated pair interconnect structures.

### BRIEF DESCRIPTION OF THE DRAWINGS

FIGS. 1a-1c illustrate a semiconductor wafer with a plurality of semiconductor die separated by a saw street;

FIGS. 2a-2o illustrate forming encapsulated pair interconnect structures;

FIGS. 3a-3h illustrate forming semiconductor packages with the encapsulated pair interconnect structures;

FIGS. 4a and 4b illustrate a backgrinding option for the encapsulated pair interconnect structures;

FIGS. 5a-5h illustrate optional configurations for the encapsulated pair interconnect structures; and

FIGS. 6a and 6b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

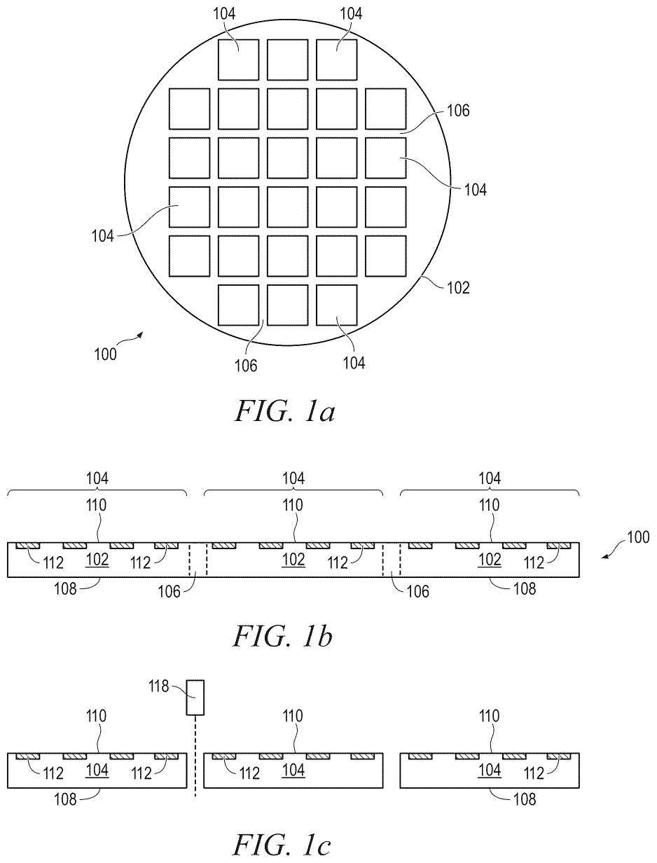

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

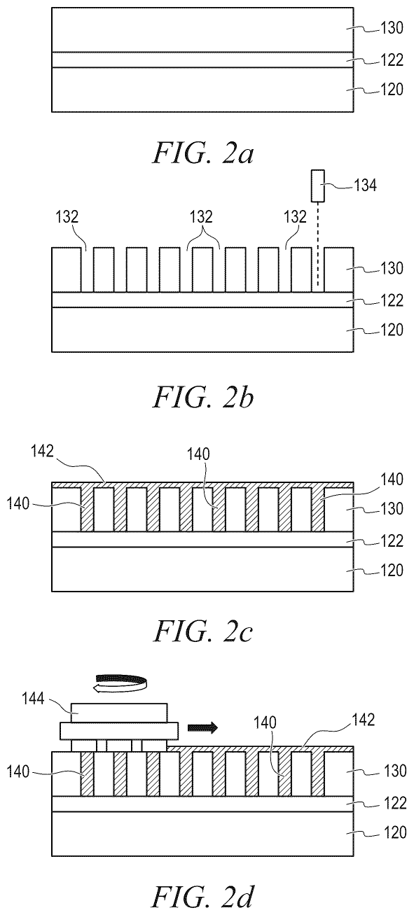

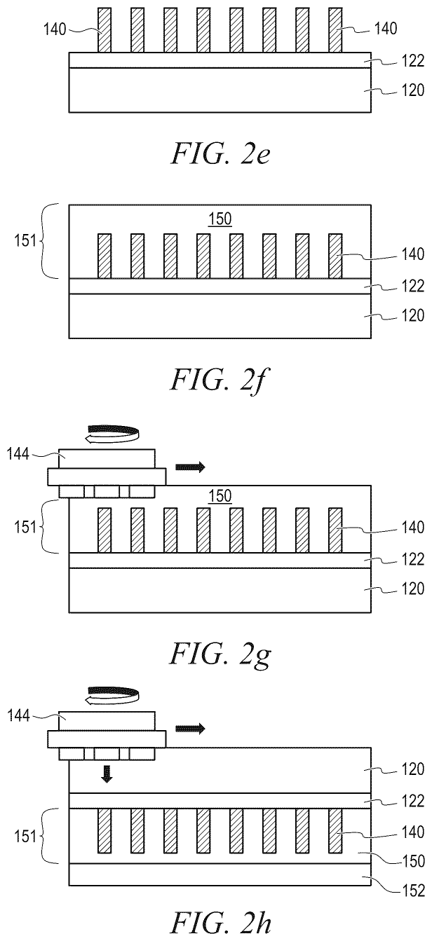

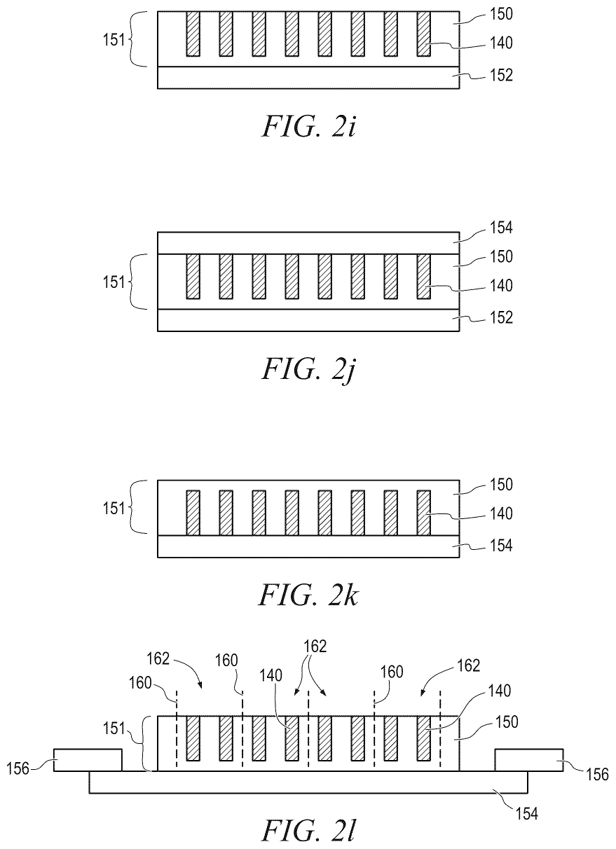

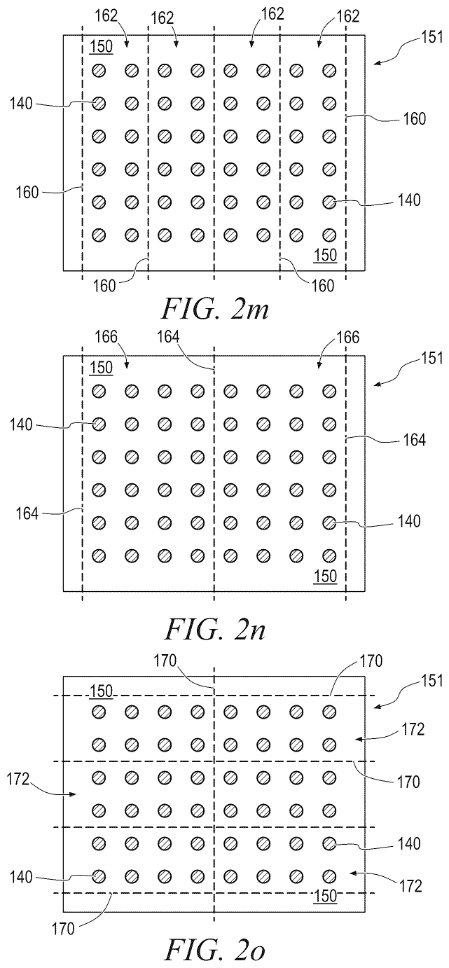

FIGS. 2a-2o illustrate the formation of encapsulated pair interconnect structures for inclusion in a semiconductor package along with semiconductor die 104. FIG. 2a shows a carrier 120 with an optional interface layer, debonding adhesive layer, or double-sided tape 122 formed or disposed over carrier 120 as a temporary adhesive bonding film, etch-stop layer, thermal release layer, or UV release layer. Carrier 120 contains sacrificial base material such as silicon, polymer, beryllium oxide, glass, or other suitable low-cost, rigid material for structural support. The term carrier can refer to just carrier 120 or the combination of carrier 120 and adhesive layer 122. Carrier 120 is an 8-inch diameter silicon wafer in some embodiments.

A mask or photoresist layer 130 is formed on carrier 120. Photoresist layer 130 may be formed using spin coating, spray coating, lamination, film-assisted molding or any other suitable method. Materials for photoresist layer 130 include photosensitive polyimide (PSPI), epoxy-based photoresists, acrylic-based photoresists, or any other suitable material. The thickness of photoresist layer 130 may vary depending on the desired conductive pillar dimensions and subsequent process requirements.

Photoresist layer 130 is used as a mask by forming openings 132 completely through the photoresist layer in FIG. 2b to expose carrier 120, or adhesive layer 122 if used. Openings 132 are formed by laser ablation using a laser 134. In other embodiments, photolithography is used to form openings 132 by applying a patterned mask to photoresist layer 130, exposing selected areas to light, and developing the exposed or unexposed regions to form the openings. Openings 132 can be formed using any other suitable method. The dimensions and placement of openings 132 are tailored based on the specific application and desired electrical performance. Openings 132 are formed completely through photoresist layer 130 but could also be formed only partially into the photoresist layer.

In FIG. 2c, conductive pillars 140 are formed by filling openings 132 with conductive material. Conductive pillars 140 can be formed of any of the materials described above for conductive layer 112 and deposited using any of the above-mentioned methods. Conductive material is typically deposited to overfill openings 132 as shown, with a portion 142 of the conductive material physically connecting each pillar 140 and covering the top surface of photoresist layer 130. Alternatively, openings 132 can be filled just to the top of, or short of the top of, photoresist layer 130 to reduce the need for a backgrinding step.

FIG. 2d shows backgrinding with a grinder 144 to remove portion 142 and leave conductive pillars 140 physically and electrically isolated from each other. Top surfaces of pillars 140 are made coplanar to photoresist layer 130.

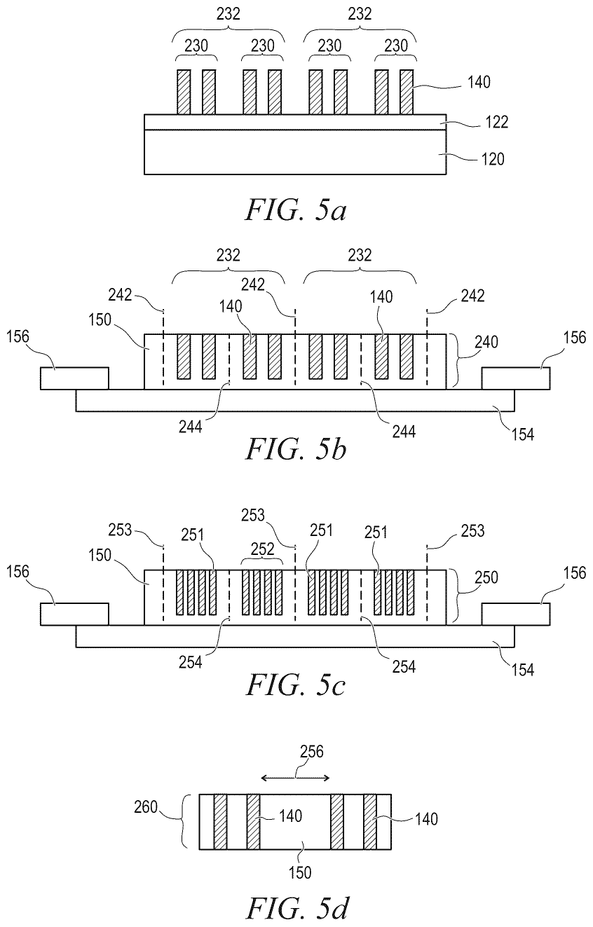

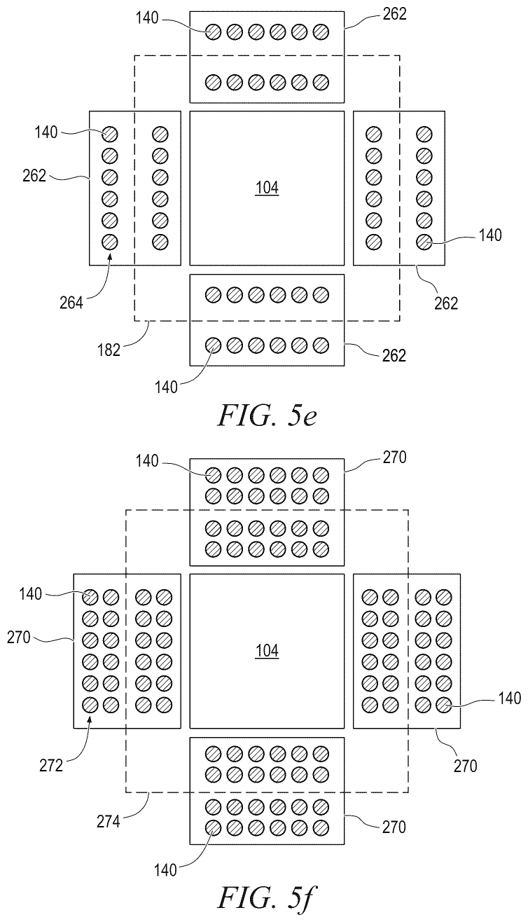

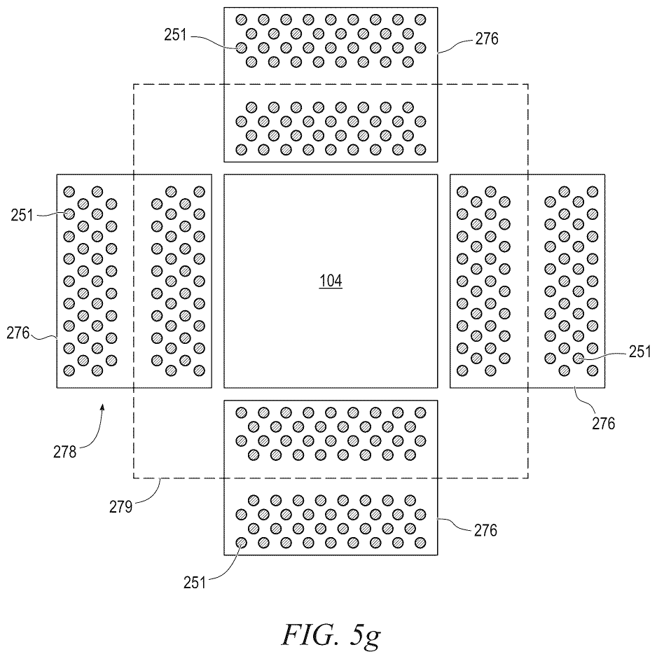

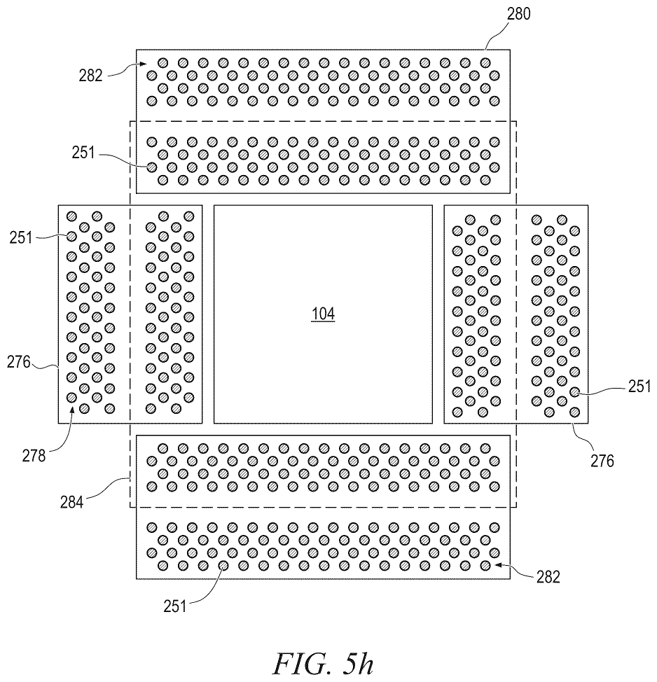

Photoresist layer 130 is removed in FIG. 2e, leaving behind conductive pillars 140 on carrier 120. Photoresist layer 130 can be removed by wet stripping, plasma ashing, thermal decomposition, or any other suitable method. Upon removal, conductive pillars 140 remain on carrier 120 in the desired pattern. In one embodiment, carrier 120 is completely covered with pillars 140 spaced at a uniform interval across an entire footprint of the carrier, with an optional margin remaining around the perimeter of the carrier. In other embodiments, additional gaps are left between some pillars 140 as saw streets, as explained below and illustrated in FIGS. 5a-5h. In some embodiments, pillars 140 are disposed or formed on carrier 120 in other methods besides as illustrated above in FIGS. 2a-2d, e.g., by forming the pillars separately and then picking and placing the pillars onto the carrier.

A molding compound or encapsulant 150 is deposited over carrier 120 and conductive pillars 140 in FIG. 2f to form a panel or wafer 151. Encapsulant 150 is deposited using a paste printing, compression molding, transfer molding, liquid encapsulant molding, vacuum lamination, spin coating, or other suitable applicator. Encapsulant 150 can be liquid or granular polymer composite material, such as epoxy resin, epoxy acrylate, or another suitable polymer, with or without a filler. Encapsulant 150 is non-conductive, provides structural support, and environmentally protects the semiconductor device from external elements and contaminants.

Encapsulant 150 is deposited to completely cover the top surfaces of conductive pillars 140. In other embodiments, film-assisted molding or another technique is used to deposit encapsulant 150 with conductive pillars 140 remaining exposed from the encapsulant. In FIG. 2g, grinder 144 or another suitable mechanism is used to remove a portion of encapsulant 150 over conductive pillars 140 while the conductive pillars remain covered by the encapsulant. In some embodiments, encapsulant 150 remains over the tops of conductive pillars 140 by 20 micrometers (μm) after backgrinding.

In FIG. 2h, a backgrinding tape 152 is mounted onto the just-grinded surface of encapsulant 150 and conductive pillars 140. Panel 151 is flipped so that backgrinding tape 152 is down and carrier 120 is oriented upward and available for grinding with grinder 144. In some embodiments, grinder 144 is a different grinder, or has a different grinding head or other part, with a different grit rating more suitable for removing carrier 120. Grinder 144 grinds away carrier 120 beginning at the top and continuing to grind until the carrier is completely removed. Adhesive layer 122 is removed by the grinding process, or by using a separate washing, peeling, etching, or other removal process. In some embodiments, carrier 120 is removed by UV release, thermal release, or another suitable means rather than grinding.

FIG. 2i shows backgrinding tape 152 supporting encapsulant 150 with conductive pillars 140 exposed where carrier 120 was removed. In FIG. 2j, a second backgrinding tape 154 is mounted onto encapsulant 150 opposite the first backgrinding tape 152. Backgrinding tape 152 is removed in FIG. 2k. FIG. 2l shows backgrinding tape 152 mounted in a metal frame 156. Metal frame 156 provides a mechanism for holding panel 151 during singulation. Backgrinding tape 156 can be mounted onto frame 156 before or after panel 151 is mounted onto the backgrinding tape.

FIGS. 2l and 2m illustrate saw streets 160 for the singulation of panel 151 into a plurality of encapsulated pair interconnect structures 162. FIG. 2l shows a cross-sectional view while FIG. 2m shows a plan view. Encapsulated pair interconnect structures 162 are referred to as encapsulated because the interconnect structures, i.e., conductive pillars 140, are encapsulated within encapsulant 150. The term pair in the phrase encapsulated pair interconnect structures 162 refers to the way that conductive pillars 140 are distributed in a symmetrical manner within the footprint of each unit, with each individual pillar 140 having a second individual pillar 140 symmetrically located as a pair within the same encapsulated pair interconnect structure.

Panel 151 can be singulated into encapsulated pair interconnect structures of any desired size and shape. Encapsulated pair interconnect structures 162 are formed with a length of six conductive pillars 140 and a width of two pillars 140. FIG. 2n illustrates another configuration with saw streets 164 defining cuts to form a plurality of encapsulated pair interconnect structures 166, each being four-by-six conductive pillars 140 in size. FIG. 2o shows the option to have the unit lengths in a perpendicular direction, with saw streets 170 defining the areas for encapsulated pair interconnect structures 172, each being two-by-four conductive pillars 140 in size. Any suitable length and width can be used. Each of the sawn encapsulated pair interconnect structures 162 can also be referred to as an e-bar or PCB unit. The rows and columns of pillars 140 in panel 151 are separated sufficiently such that saw streets can be defined between any two adjacent rows or columns to make encapsulated pair interconnect structures of any desired size.

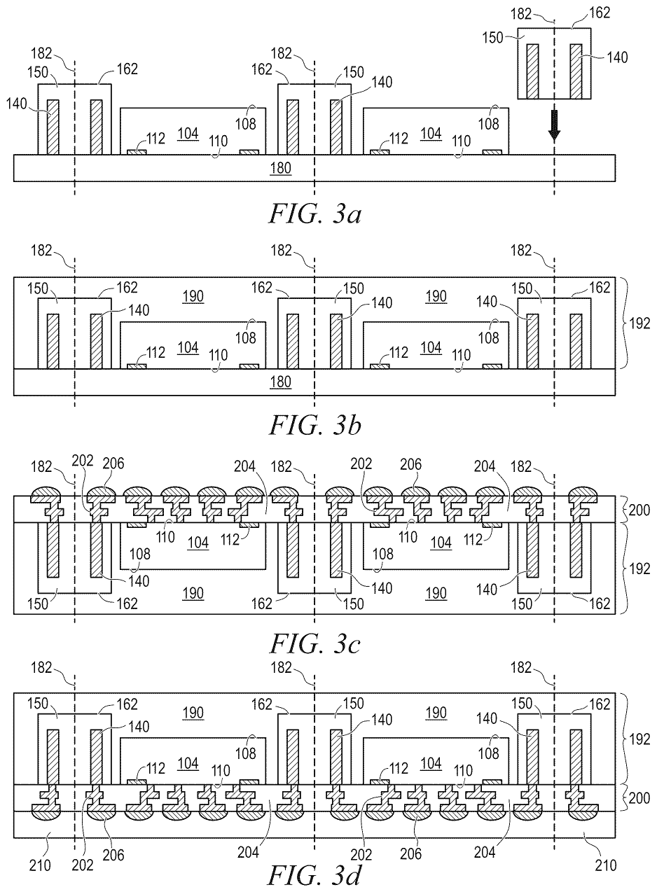

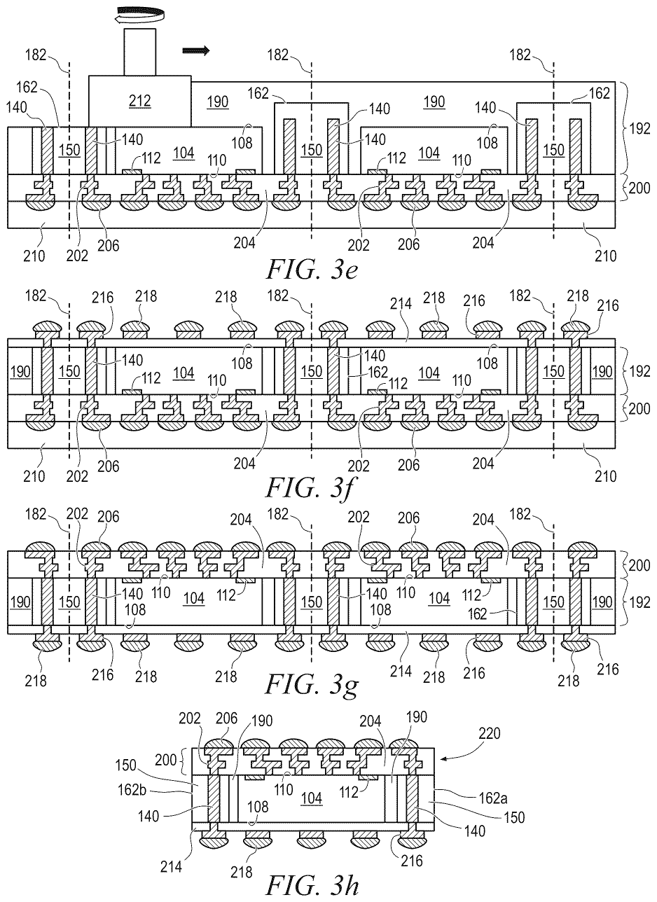

FIGS. 3a-3h illustrate forming semiconductor packages with semiconductor die 104 and encapsulated pair interconnect structures 162. In FIG. 3a, semiconductor die 104 and encapsulated pair interconnect structures 162 are disposed over a carrier 180. Carrier 180 can be any of the options described above for carrier 120 and optionally includes an adhesive or other interface layer as described above for adhesive layer 122. Semiconductor die 104 are picked and placed onto carrier 180 with active surfaces 110 oriented toward the carrier. In the illustrated embodiment, a single semiconductor die 104 is used for each final unit being manufactured, separated by saw streets 182. While only two complete units are shown, carrier 180 is generally sufficiently large to form hundreds of units together, each separated from the others by saw streets 182. Any other desired electrical components, e.g., additional semiconductor die, semiconductor packages, chiplets, or discrete active or passive components, can be disposed on carrier 180 alongside semiconductor die 104 to be included in the packages being formed.

Encapsulated pair interconnect structures 162 are disposed on or within saw streets 182 between or around semiconductor die 104 with the exposed ends of conductive pillars 140 oriented toward carrier 180. Semiconductor die 104 are typically square or rectangular, with encapsulated pair interconnect structures 162 disposed adjacent to two opposing sides of each semiconductor die, or adjacent to all four sides of each semiconductor die. Saw streets 182 run down the center or middle of each encapsulated pair interconnect structure 162 such that, after being subsequently singulated, each of the paired conductive pillars 140 will be split with one of the pair being packaged with each of the two adjacent semiconductor die 104. In the illustrated embodiment, one row of conductive pillars 140 of each encapsulated pair interconnect structure 162 goes with each adjacent semiconductor die 104. In other embodiments, wider encapsulated pair interconnect structures are used where multiple rows remain together on each side of a saw street 182. For instance, if encapsulated pair interconnect structures 166 were used, then two rows of conductive pillars 140 would remain on each side of semiconductor die 104 in each package after singulation.

In FIG. 3b, an encapsulant 190 is deposited over semiconductor die 104 and encapsulated pair interconnect structures 162 using the methods and materials described above for encapsulant 150. Encapsulant 190 fully covers semiconductor die 104 and encapsulated pair interconnect structures 162 for an entire footprint of carrier 180 and forms a reconstituted wafer 192. Reconstituted wafer 192 is so-called because semiconductor die 104 are repositioned and reassembled from wafer 100 into a new structure. The term reconstituted reflects that the original wafer 100 has been disaggregated and then reorganized into a new wafer. After encapsulation and planarization, the surface of reconstituted wafer 192 resembles that of a standard semiconductor wafer. This allows for further processing, such as redistribution layer (RDL) formation, similar to conventional wafer-level processes. Reconstituted wafer 192 functions like a traditional wafer but consists of multiple individual dies that have been encapsulated.

In FIG. 3c, carrier 180 is removed as described above for carrier 120, and a build-up interconnect structure 200 is formed over reconstituted wafer 192. Build-up interconnect structure 200 is formed by building up interleaved conductive layers 202 and insulating layers 204. The first layer formed on reconstituted wafer 192 can be a conductive layer 202 or an insulating layer 204. Each successive conductive layer 202 has an insulating layer 204 formed between it and the previous conductive layer.

Conductive layers 202 are formed using any of the processes and materials mentioned above for conductive layer 112. Insulating layers 204 contain one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other materials that have similar insulating and structural properties. Insulating layers 204 can be formed using PVD, CVD, printing, lamination, spin coating, spray coating, sintering, thermal oxidation, or other suitable means. Any insulating layer, passivation layer, dielectric layer, or encapsulant mentioned above or below can be formed using any of the materials or methods described for insulating layer 204.

Openings are formed through each insulating layer 204 to expose contacts or contact pads of an underlying conductive layer 202, or, in the case of the first insulating layer 204, to expose ends of conductive pillars 140 and contact pads of conductive layer 112. The openings can be formed by chemical etching, photolithography, mechanical drilling, laser drilling, or any other suitable means. Conductive layers 202 are formed extending through the openings in the insulating layers 204 to physically and electrically couple to the underlying conductive layers, or to conductive pillars 140 and the contact pads of conductive layer 112. Conductive layers 202 of build-up interconnect structure 200 physically and electrically contact conductive layer 112 of semiconductor die 104. Conductive layers 202 include conductive traces to fan-out or fan-in from semiconductor die 104 and optionally include contact pads at both ends of the traces for connecting to the underlying contact and for subsequent formation of overlying conductive structures.

Additional conductive layers 202 and insulating layers 204 are interleaved over reconstituted wafer 192 as needed to implement the desired electrical signal routing. Interconnect structure 192 being called a build-up interconnect structure, refers to the way that the interconnect structure is formed by successively building up insulating layers and conductive layers over reconstituted wafer 192 until the desired signal routing is achieved. Contact pads or under-bump metallization (UBM) pads are formed as part of, or on top of, the top conductive layer 202. UBM pads are optionally formed of multiple conductive layers including a wetting layer, a barrier layer, and an adhesion layer. Another passivation or solder resist layer is optionally formed over the UBM pads. UBM pads can have a flat top surface as illustrated or be formed conformally in openings of insulating layer 204.

An electrically conductive bump material is deposited over contact pads or UBM pads of the top conductive layer 202 using an evaporation, electrolytic plating, electroless plating, ball drop, or screen-printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 202 using a suitable attachment or bonding process. In one embodiment, the bump material is reflowed by heating the material above its melting point to form balls or bumps 206. Bump 206 can also be compression bonded or thermocompression bonded to conductive layer 202. Bump 206 represents one type of interconnect structure that can be formed. The interconnect structure can also use bond wires, conductive paste, stud bump, micro bump, or other electrical interconnect. The term build-up interconnect structure 200 can include bumps 206 or just the underlying insulating layers 204 and conductive layers 202.

Reconstituted wafer 192 is mounted onto a backgrinding tape 210 and flipped in FIG. 3d. In FIG. 3e, a grinder 212 or other suitable mechanism is used to reduce a thickness of reconstituted wafer 192. Encapsulant 190 is backgrinded to remove a top portion of the encapsulant until conductive pillars 140 are exposed at a new top surface of reconstituted wafer 192. In embodiments where encapsulated pair interconnect structures 162 are formed with encapsulant 150 remaining over the top ends of conductive pillars 140, backgrinding also removes a portion of encapsulant 150 to expose the conductive pillars. In some embodiments, portions of semiconductor die 104 are also removed. After backgrinding, back surfaces of semiconductor die 104, conductive pillars 140, encapsulant 150, and encapsulant 190 are all coplanar with each other.

In FIG. 3f, a backside RDL layer is formed. Insulating layer 214 is formed first as described above for insulating layer 204. A conductive layer 216 is formed over insulating layer 214 as described above for conductive layer 216. Conductive layer 216 includes contact pads for external interconnect and, optionally, conductive traces to fan-in or fan-out electrical connections from conductive pillars 140. Solder bumps 218 are formed on contact pads or UBM of conductive layer 216 as described above for solder bumps 206. In some embodiments, a build-up interconnect structure, similar to build-up interconnect structure 200, is formed over the back side of reconstituted wafer 192, including multiple insulating and conductive layers interleaved over each other.

FIG. 3g shows reconstituted wafer 192 after processing and before singulation. FIG. 3h shows a semiconductor package 220 produced by singulating reconstituted wafer 192 through saw streets 182. Each encapsulated pair interconnect structure 162 is cut in half by the singulation, producing two halves 162a and 162b. Each unit includes one half of each adjacent encapsulated pair interconnect structure 162. Package 220 in FIG. 3h includes a half 162a from the encapsulated pair interconnect structure 162 on the right, and a half 162b from the encapsulated pair interconnect structure on the left. Each conductive pillar 140 had a paired conductive pillar in the same encapsulated pair interconnect structure 162 that has been separated into another semiconductor package 220.

Package 220 is a semiconductor package using encapsulated pair interconnect structures 162 for vertical interconnect. Using encapsulated pair interconnect structures 162 during the manufacturing process increases the aspect ratio of pre-formed vertical interconnects that a package can use, because each package doubles the width of its vertical interconnect block by combining into an encapsulated pair interconnect structure 162 with an adjacent semiconductor package.

Instead of each package 220 being formed with its own interconnect structure with a single row of conductive pillars 140, pick-and-place occurs with double-rows of conductive pillars, effectively doubling the width of each interconnect unit that has to be picked-and-placed without changing the total number of vertical conductive pillars 140 being used. Doubling the width of each picked-and-placed interconnect block, e.g., encapsulated pair interconnect structures 162, increases the maximum length that can be used while staying within the allowable aspect ratio for the pick-and-place process being used.

For instance, if the aspect-ratio requirements of a certain process dictates a maximum length of four conductive pillars 140 when a width of one conductive pillars is used (a maximum aspect ratio of 4:1), pairing up the pillars into interconnect structures 162 allows a maximum length of eight conductive pillars instead of four. Therefore, package 220 is formed with an effective maximum one-by-eight block of conductive pillars 140 by doubling the conductive pillars into encapsulated pair interconnect structures 162. In this example, the maximum size of a conductive pillar block without doubling, i.e., without paired conductive pillars, would have been one-by-four. In practice, encapsulated blocks of conductive pillars 140 are typically significantly larger, but the same effect of pairing to increase width in order to increase the maximum length holds for any size.

Increasing the width of each individual module that has to be picked-and-placed increases structural rigidity to increase pick and place throughput performance. Package 220 leverages existing capability of embedded wafer-level ball-grid array manufacturing technology to enable double-sided RDL with molded e-Bars as vertical interconnect.

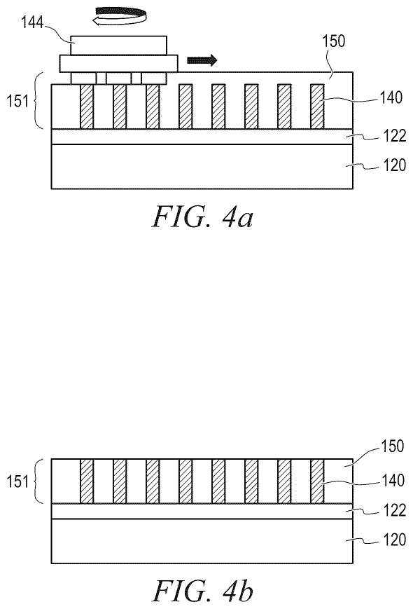

FIGS. 4a and 4b illustrate an alternative embodiment of forming encapsulated pair interconnect structures 162. FIG. 4a continues from FIG. 2g above. Grinder 144 continues to grind away at encapsulant 150 until enough encapsulant is removed to expose the tops of conductive pillars 140. In some embodiments, a top portion of conductive pillars 140 is also removed. FIG. 4b shows panel 151 after backgrinding. Each conductive pillar 140 has both a top and a bottom end that is coplanar to a surface of encapsulant 150. The manufacturing of encapsulated pair interconnect structures 162 proceeds as shown in FIGS. 2h-2o, but results in encapsulated pair interconnect structures with conductive pillars 140 exposed at both ends. Any of the above or below embodiments can be ground to expose both ends of conductive pillars 140 during the encapsulated pair interconnect structure manufacturing stage.

FIGS. 5a-5h illustrate additional alternative or optional configuration options for encapsulated pair interconnect structures. In FIG. 5a, conductive pillars 140 are grouped into a grouping 230 for each of the eventual packages that the pillars will end up in. The groupings 230 can be formed by moving each conductive pillar 140 closer together within the group, by increasing the sizes of gaps between pillars across saw streets, or a combination of both. Grouping conductive pillars 140 into groups 230 increases margins for singulating by having wider saw streets than the gaps between conductive pillars within the groups. Each group 230 is paired with another group 230, such that each individual pillar 140 is paired with another individual pillar 140 in an adjacent group 230, to form encapsulated pair interconnect structures 232.

FIG. 5b shows a panel 240 with groupings 230 after deposition of encapsulant 150. FIG. 5b is equivalent to the step in FIG. 2l, but with panel 240 having groupings 230 instead of each pillar 140 being equally spaced across the entire panel footprint. Saw streets 242 show where singulation occurs at this stage to form encapsulated pair interconnect structures 232. Saw streets 244 remain between each pair of groupings 230 for later singulation along with the final semiconductor packages being formed. The gaps between conductive pillars 240 can be the same width, or different, for saw streets 242 compared to saw streets 244.

FIG. 5c illustrates another embodiment where panel 250 has thinner conductive pillars 251 formed closer-together within groupings 252. With narrower and closer-together pillars 251 compared to pillars 140, four rows of pillars are possible in the same group size as was used for two rows above. Pillars 251 are formed using the same process and materials as described above for pillars 140. Groups 252 are cut in pairs at saw streets 253 to form encapsulated pair interconnect structures. Saw streets 254 are areas reserved for later singulation along with final semiconductor packages.

The gaps 256 between groupings of pillars can be increased or decreased as shown in FIG. 5d with panel 260. In one embodiment, gap 256 is between 250 μm and 500 μm. In other embodiments, any suitable gap size is used.

FIGS. 5e-5h illustrate plan views of panels of devices being formed as shown in FIGS. 3a-3h. FIG. 5e is an embodiment similar to semiconductor package 220. Each encapsulated pair interconnect structure 262 in FIG. 5e has groupings 264 of pillars 140 with two rows per encapsulated pair interconnect structure. Saw street 182, which will separate the illustrated unit from adjacent units, extends directly between the groupings 264 of each encapsulated pair interconnect structure 262. After singulation, the closer grouping 264 from each encapsulated pair interconnect structure 262, that grouping within the boundary of saw street 182, will remain packaged with semiconductor die 104.

FIG. 5f illustrates an embodiment where encapsulated pair interconnect structures 270 have groupings 272 of pillars 140. Each grouping 272 has two rows of pillars 140. When the device is singulated through saw street 274, two rows of pillars 140 from each encapsulated pair interconnect structures 270, those within the saw street boundary, will remain within the package on each side of semiconductor die 104. Encapsulated pair interconnect structures can be made with any desired number and length of rows per group of pillars.

FIG. 5g shows encapsulated pair interconnect structures 276 with groupings 278 of pillars 251. Pillars 251 are thinner than pillars 140, as seen in plan view, and so four rows of pillars 251 can be used for each grouping 278. In addition to being thinner, with more rows possible, groupings 278 have pillars 251 offset from each other in each row. Each successive row moving away from semiconductor die 104 has pillars 251 disposed between pillars of the previous row, rather than directly aligned. One grouping 278 remains on each side of semiconductor die 104 in a semiconductor package after singulation through saw street 279.

FIG. 5h shows an embodiment with two opposing sides of semiconductor die 104 having longer encapsulated pair interconnect structures 280. Groupings 282 of pillars 251 are similar to groupings 278 but extend for a greater length as part of the longer encapsulated pair interconnect structures 280. Encapsulated pair interconnect structures 280 extend all the way to, or nearly to, the saw streets 284 running perpendicular to the encapsulated pair interconnect structure. Using longer encapsulated pair interconnect structures 280 that extend to one or both perpendicular saw streets allows more footprint area to be filled with pillars 251 or 140. In one embodiment, each of the four encapsulated pair interconnect structures extends to one adjacent perpendicular saw street while only extending to the edge of semiconductor die 104 in the opposite direction.

Any of the encapsulated pair interconnect structure and grouping embodiments shown in FIGS. 5a-5h, and variations thereof, can be used in any of the other above embodiments. Grouping configurations can be mixed and matched on different sides of semiconductor die 104. Some embodiments do not include encapsulated pair interconnect structures on all four sides of semiconductor die 104.

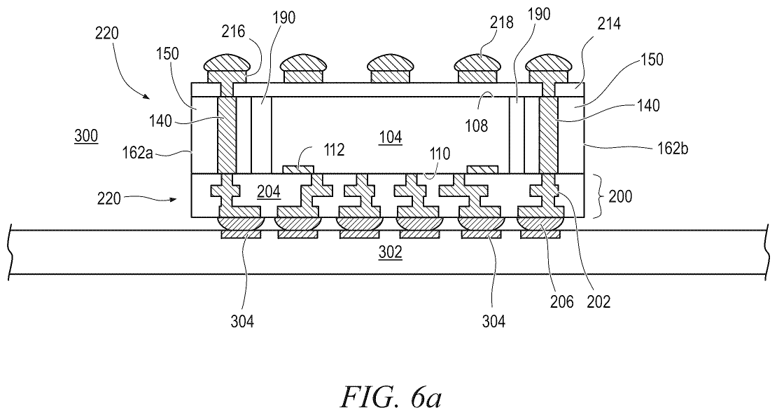

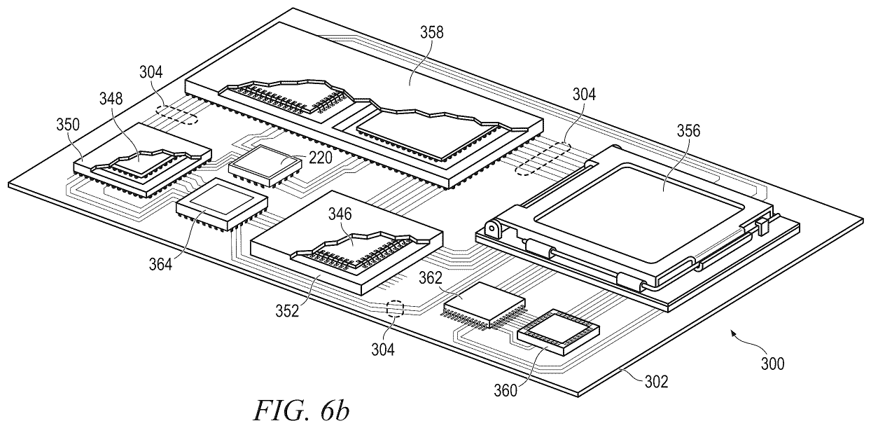

FIGS. 6a and 6b illustrate integrating the above-described semiconductor packages, e.g., semiconductor package 220, into a larger electronic device 300. FIG. 6a illustrates a partial cross-section of semiconductor package 220 mounted onto a printed circuit board (PCB) or other substrate 302 as part of electronic device 300. Solder bumps 206 are reflowed onto conductive layer 304 of PCB 302 to physically attach and electrically connect semiconductor package 220 to the PCB. In other embodiments, thermocompression or another suitable attachment and connection methods are used. In some embodiments, an adhesive or underfill layer is used between semiconductor package 220 and PCB 302. Semiconductor die 104 is electrically coupled to conductive layer 304 through bumps 206 and build-up interconnect structure 200. Contact pads or UBM of conductive layer 216 and optional solder bumps 218 can be used to form a stacked package.

FIG. 6b illustrates electronic device 300 having a chip carrier substrate or PCB 302 with a plurality of semiconductor packages disposed on a surface of PCB 302, including semiconductor package 220. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 6b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
forming a plurality of encapsulated pair interconnect structures by,
providing a carrier,
disposing a first conductive pillar and second conductive pillar over the carrier for each encapsulated pair interconnect structure, and
depositing a first encapsulant over the first conductive pillars and second conductive pillars;
providing a semiconductor die;
disposing a first encapsulated pair interconnect structure and second encapsulated pair interconnect structure from the plurality of encapsulated pair interconnect structures adjacent to two opposite sides of the semiconductor die;
depositing a second encapsulant over the semiconductor die, first encapsulated pair interconnect structure, and second encapsulated pair interconnect structure to form a panel;
forming a build-up interconnect structure over the panel; and
singulating the panel through the first encapsulated pair interconnect structure and second encapsulated pair interconnect structure between the respective first conductive pillar and second conductive pillar of each encapsulated pair interconnect structure.

2. The method of claim 1, further including forming the plurality of encapsulated pair interconnect structures to each include a first row of conductive pillars including the first pillar and a second row of conductive pillars including the second conductive pillar.

3. The method of claim 1, further including backgrinding the first encapsulant to expose the first conductive pillars and second conductive pillars as part of the process of forming the plurality of encapsulated pair interconnect structures.

4. The method of claim 1, further including removing the carrier by backgrinding prior to disposing the first encapsulated pair interconnect structure and second encapsulated pair interconnect structure adjacent to the semiconductor die.

5. The method of claim 1, wherein each of the first conductive pillars is configured in a respective first grouping of conductive pillars and each of the second conductive pillars is configured in a respective second grouping of conductive pillars.

6. The method of claim 5, wherein each of the first groupings and second groupings includes a plurality of offset conductive pillar rows.

7. A method of making a semiconductor device, comprising:
forming an encapsulated pair interconnect structure by,
providing a first conductive pillar and second conductive pillar, and
depositing a first encapsulant over the first conductive pillar and second conductive pillar;
providing a semiconductor die;
disposing the encapsulated pair interconnect structure adjacent to the semiconductor die;
depositing a second encapsulant over the semiconductor die and encapsulated pair interconnect structure to form a panel;
forming a build-up interconnect structure over the encapsulant, semiconductor die, and encapsulated pair interconnect structure; and
singulating the panel through the encapsulated pair interconnect structure between the first conductive pillar and second conductive pillar.

8. The method of claim 7, further including forming the encapsulated pair interconnect structure to include a first row of conductive pillars including the first pillar and a second row of conductive pillars including the second conductive pillar.

9. The method of claim 7, further including backgrinding the first encapsulant to expose the first conductive pillar and second conductive pillar as part of the process of forming the encapsulated pair interconnect structure.

10. The method of claim 7, further including:
disposing the first conductive pillar and second conductive pillar on a carrier; and
removing the carrier by backgrinding prior to disposing the encapsulated pair interconnect structure adjacent to the semiconductor die.

11. The method of claim 7, wherein the first conductive pillar is configured in a first grouping of conductive pillars and the second conductive pillar is configured in a second grouping of conductive pillars.

12. The method of claim 11, wherein the first grouping and second grouping each includes a plurality of offset conductive pillar rows.

13. The method of claim 7, further including disposing a second encapsulated pair interconnect structure adjacent to the semiconductor die.

14. A method of making a semiconductor device, comprising:
providing a semiconductor die;
disposing an encapsulated pair interconnect structure adjacent to the semiconductor die;
depositing an encapsulant over the semiconductor die and encapsulated pair interconnect structure to form a panel;
forming a build-up interconnect structure over the encapsulant, semiconductor die, and encapsulated pair interconnect structure; and
singulating the panel through the encapsulated pair interconnect structure.

15. The method of claim 14, further including forming the encapsulated pair interconnect structure to include a first row of conductive pillars and a second row of conductive pillars.

16. The method of claim 14, wherein the encapsulated pair interconnect structure includes a plurality of conductive pillars, and each of the conductive pillars is exposed at two ends of the respective conductive pillar.

17. The method of claim 14, further including:
forming encapsulated pair interconnect structure on a carrier; and
removing the carrier by backgrinding prior to disposing the encapsulated pair interconnect structure adjacent to the semiconductor die.

18. The method of claim 14, wherein the encapsulated pair interconnect structure includes a first grouping of conductive pillars and a second grouping of conductive pillars.

19. The method of claim 18, wherein the first grouping and second grouping each includes a plurality of offset conductive pillar rows.

20. The method of claim 14, further including disposing a second encapsulated pair interconnect structure adjacent to the semiconductor die.

21. A semiconductor device, comprising:
a semiconductor die;
an encapsulated pair interconnect structure disposed adjacent to the semiconductor die;
an encapsulant deposited over the semiconductor die and encapsulated pair interconnect structure; and
a build-up interconnect structure formed over the encapsulant, semiconductor die, and encapsulated pair interconnect structure.

22. The semiconductor device of claim 21, wherein the encapsulated pair interconnect structure includes a first row of conductive pillars and a second row of conductive pillars.

23. The semiconductor device of claim 21, further including a conductive layer formed over the semiconductor die, encapsulated pair interconnect structure, and encapsulant opposite the build-up interconnect structure.

24. The semiconductor device of claim 21, wherein the encapsulated pair interconnect structure includes a first grouping of conductive pillars and a second grouping of conductive pillars.

25. The semiconductor device of claim 24, wherein the first grouping and second grouping each includes a plurality of offset conductive pillar rows.
